(19) United States
(12) Patent Application Publication
(10) Pub. No.: US 2019/0043778 A1
(43) Pub. Date: Feb. 7, 2019

(54) SWAGING PROCESS FOR COMPLEX INTEGRATED HEAT SPREADERS

(71) Applicant: Intel Corporation, Santa Clara, CA (US)

(72) Inventors: Zhizhong TANG, Tempe, AZ (US); Shinobu KOURAKATA, Tsukuba-shi (JP); Kazuo OGATA, Tsukuba (JP); Paul R. START, Chandler, AZ (US); Syadwad JIAN, Chandler, AZ (US); William Nicholas LABANOK, Gilbert, AZ (US); Wei HU, Chandler, AZ (US); Peng LI, Chandler, AZ (US); Douglas R. YOUNG, Tempe, AZ (US); Gregory S. CONSTABLE, Chandler, AZ (US); John J. Beatty, Chandler, AZ (US); Pardeep K. BHATTI, Gilbert, AZ (US); Luke J. GARNER, Chandler, AZ (US); Aravindha R. ANTONISWAMY, Phoenix, AZ (US)

(21) Appl. No.: 16/061,324

(22) PCT Filed: Dec. 26, 2015
(86) PCT No.: PCT/US2015/000397

§ 371 Date: Jun. 11, 2018

(51) Int. Cl. H01L 23/367; H01L 21/48; H01L 25/065

(52) U.S. Cl. CPC H01L 23/3675; H01L 25/0655; H01L 21/4882

(57) ABSTRACT

Embodiments are generally directed to a swaging process for complex integrated heat spreaders. An embodiment of an integrated heat spreader includes components, each of the components including one or more swage points; and a multiple swage joints, each swage joint including a swage pin joining two or more components, wherein components are joined into a single integrated heat spreader unit by the swage joints.

### TECHNICAL FIELD

Embodiments described herein generally relate to the field of electronic devices and, more particularly, to a swaging process for complex integrated heat spreaders.

### BACKGROUND

In electronic devices, in order meet the increasing demand for high performance and low cost, the processer packaging architecture has become more and more complex, including multiple chips and packages.

The creation of such complex processor packaging solutions creates a need for cooling structures that are generated for the complex structures. The resulting structures can be large and can include varying numbers of cavities, as well as varying height structures among the cavities of a heat spreader.

In conventional fabrication of an integrated heat spreader, a single piece of metal, commonly copper, is stamped out utilizing a stamping machine. The resulting heat spreader includes the required features of the integrated heat spreader, including each required cavity within the heat spreader structure.

However, the cost of conventional generation of integrated heat spreaders increases quickly with structural complexity because the structures require larger (higher tonnage) and more expensive stamping machines to accomplish the stamping process. If the cost of the heat spreader becomes too high, then the particular processor package architecture becomes impractical due to the subsidiary cost of heat spreader fabrication.

### BRIEF DESCRIPTION OF THE DRAWINGS

Embodiments described here are illustrated by way of example, and not by way of limitation, in the figures of the accompanying drawings in which like reference numerals refer to similar elements.

FIG. 1 is an illustration of an integrated heat spreader including multiple joined swage components according to an embodiment;

FIG. 2 is an illustration of a multiple chip packaging device to be constructed of multiple joined components according to an embodiment;

FIG. 3 is an illustration of a patch on interposer device to be constructed of multiple joined components according to an embodiment;

FIGS. 4A and 4B illustrate a swaging process according to an embodiment;

FIG. 5 illustrates an integrated heat spreader including joint parts according to an embodiment;

FIG. 6A is an illustration of a frame structure for construction of an integrated heat structure according to an embodiment;

FIG. 6B is an illustration of a combined unit including a frame structure for construction of an integrated heat structure according to an embodiment;

FIG. 7 is an illustration of components for construction of an integrated heat structure according to an embodiment; and

FIG. 8 is a flow chart to illustrate a process for fabrication of an integrated heat spreader using multiple joined components according to an embodiment.

### DETAILED DESCRIPTION

Embodiments described herein are generally directed to a swaging process for complex integrated heat spreaders.

For the purposes of this description:

“Integrated heat spreader” or “IHS” refers to an apparatus to interface between an electronic device, including a microprocessor or other device that produces significant heat, and a cooling solution such as a heat sink.

“Swaging” refers to a process in which portions of a device are mechanically joined using swage pins, wherein a swage pin is mechanically deformed provide connection. Swaging includes, but is not limited to, a riveting process.

“Swage point” means either a swage hole for passage of a swage pin, or an installed swage pin.

“Mobile electronic device” or “mobile device” refers to a smartphone, smartwatch, tablet computer, notebook or laptop computer, handheld computer, mobile Internet device, wearable technology, or other mobile electronic device that includes processing capability.

In the formation of integrated heat spreaders for complex apparatuses, the cost of machining and assembly is increasing greatly with the complexity of design. As more complex designs require larger stamping machines, which are much more expensive to purchase on operation to provide the metal formation, there is a need to simplify the machining required to construct an integrated heat structure. Further, the solution must be capable of providing the same heat conduction properties and other features as a conventionally produced integrated heat spreader.

In some embodiments, a complex integrated heat spreader is constructed using multiple sections of the heat spreader apparatus that individually stamped out, and then interconnected using a swaging process. In some embodiments, a complex heat spreader design is divided into multiple smaller heat spreader components or parts, wherein each section is less complex for stamping than the complete spreader. In some embodiments, because each of the separate section may be machined with a smaller machine, there is a potential for significant reduction in overall machining costs.

In some embodiments, each separate section is stamped from a metal, such as copper. However, embodiments are not limited to the fabrication using a particular material.

In some embodiments, instead of forming an ultra large IHS by stamping, required high tonnage machines, a process utilizes a low tonnage machine to make multiple small and simple components. The multiple smaller components are then joined together by swaging technology. The swage joining is low cost and provides high efficiency, and has been demonstrated in automotive, electronics, and other industries.

In some embodiments, each heat spreader component includes one or more swaging points, wherein the one or more swaging points of each component align with swaging points of one or more of the other components of the integrated heat spreader. Each swage point may be a swage hole or a swage pin.

In some embodiments, separate elements of an integrated heat spreader are joined with the use of swage pins, wherein the swage pins are mechanically deformed to form swage joints, and to thus create a combined integrated heat spreader. Because the swage pin assembly is generally unaffected by heat, and because an integrated heat assembly is essentially a static device in operation, a swaging process is well suited for the task.

Upon constructing an integrated heat spreader from swaged components, there generally are no tooling or processing changes necessary to install such a combined IHS. The constructed integrated heat spreader can behave as a conventional IHS in packaging and assembly, and operate in a same manner with regard to reliability and performance.

Swage holes may commonly be punched out of the components of the integrated heat spreader, rather requiring drilling. Further, swage pins will commonly be installed into holes of components. However, embodiments are not limited to a particular process for generation or installation of swage holes or pins.

In some embodiments, a swaging process may include the fabrication of a frame structure that includes one or more frame openings. In some embodiments, a swaging process further includes the fabrication of inserts to be joined into a frame structure to provide a complete integrated heat spreader.

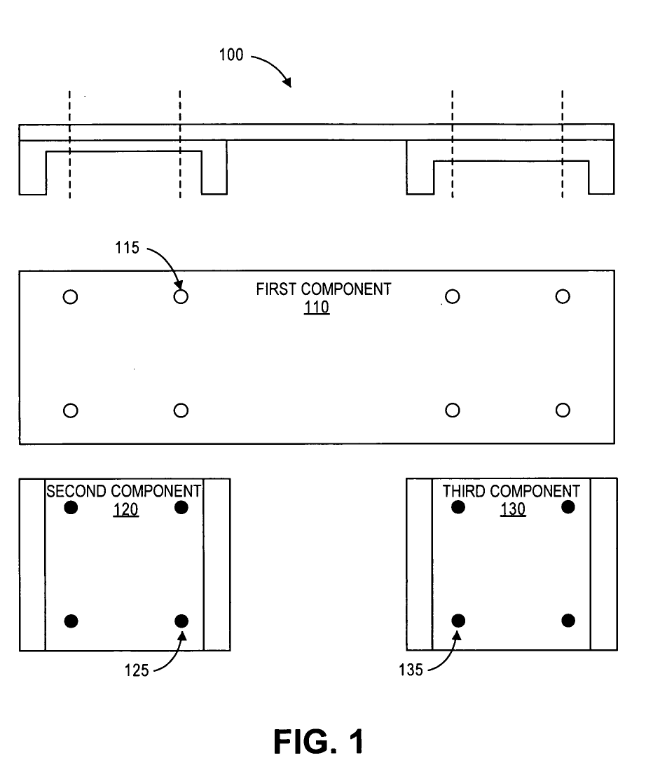

FIG. 1 is an illustration of an integrated heat spreader including multiple joined swage components according to an embodiment. In some embodiments, a complex integrated heat spreader is shown in a simplified drawing in FIG. 1. As illustrated, a complex heat spreader 100 includes cavities for each of the devices, thus creating a difficult and expensive machining process. Actual heat spreader designs may include complex shapes and angles than are provided in this example.

In some embodiments, the complex integrated heat spreader is constructed instead of multiple heat spreader components or parts, wherein each of the components is a less complex component that requires less stamping effort and cost than the full integrated heat spreader 100. Stated in another way, each component includes a simpler structure than the full integrated heat spreader.

In the illustrated example, the integrated heat spreader is constructed of a first component 110, the first component 110 in this example being a top heat shield component; a second component 120, which is a first heat spreader cavity; and a third component 130, which is second heat spreader cavity. It is noted that this is an example, and the design of the full integrated heat spreader 100 may be divided in different ways depending on the particular needs are for the integrated heat spreader.

In some embodiments, each of the multiple components 110, 120, and 130 includes one or more swaging points, wherein each of the one or more swaging points of a component aligns with a swaging point of another component. Each swaging point is either a swage hole or a swage pin.

In the example provided in FIG. 1, first component 110 includes eight swage holes 115; second component 120 includes four swage pins 125; and the third component 130 includes four swage pins 135. In this example, a first set of four swage points 115 of the first component align with the swage points 125 of the second component 125, and a second set of four swage points 115 of the first component 110 align with the swage points 135 of the third component 130.

In some embodiments, a joined integrated heat spreader 100 includes multiple spreader components are joined permanently into a single unit using a swaging process.

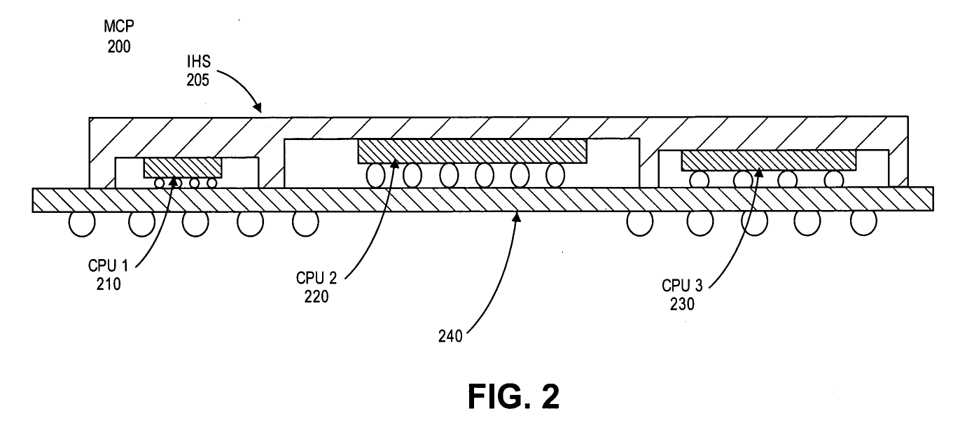

FIG. 2 is an illustration of a multiple chip packaging device to be constructed of multiple joined components according to an embodiment. In this illustration, a multiple chip packaging (MCP) 200 includes multiple chips, the chips being CPU 1 (210), CPU 2 (220), and CPU 3 (230), within a package on a substrate 240. The MCP includes an integrated heat spreader 210 that includes a separate cavity of a different cavity depth for each chip.

In some embodiments, a design for the integrated heat spreader 205 is divided into multiple components, each component including swage points that align with one or more of the other components. In some embodiments, an integrated heat spreader including multiple joined swage components is constructed to simplify the stamping for the required heat spreader. In one example, the integrated heat spreader may be constructed of components that are similar to the components illustrated in FIG. 1, but this is simply an example, and other designs may also be implemented.

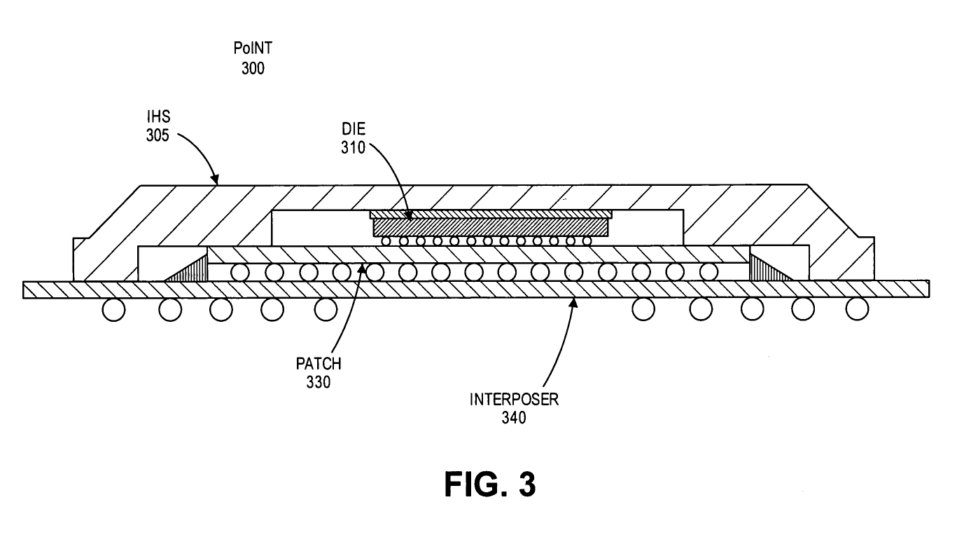

FIG. 3 is an illustration of a patch on interposer device to be constructed of multiple joined components according to an embodiment. As illustrated, a patch on interposer (PoINT) device 300 includes a die installed on a patch element 330, wherein the patch 330 is installed on an interposer 340. As a result, an integrated heater spreader 305 for the PoINT device 300 includes a “cavity in cavity” feature to allow for the patch attachment with the interposer, while also providing the head spreading function for the die 310.

Because the integrated heat spreader 305 in this example is complex and expensive to stamp in a single piece, the HIS 305 is again constructed of multiple components that are permanently joined in a swaging process.

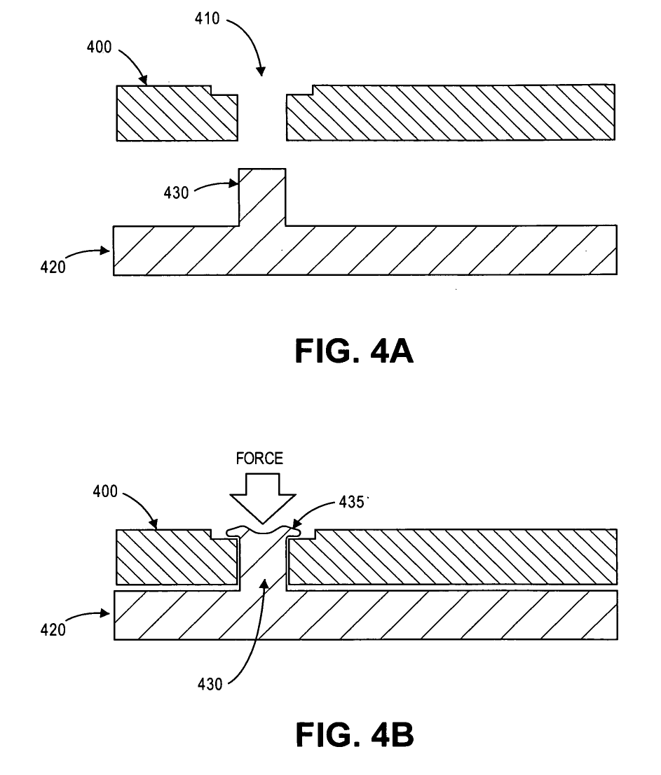

FIGS. 4A and 4B illustrate a swaging process according to an embodiment. As illustrated in FIG. 4A, a first component 400 may include one or more swage holes 410 and a second component may have an aligned swage point providing a swage pin 430. A swage hole 410 may include a countersink as shown in FIG. 4A.

FIG. 4B illustrates components 400 and 420 being permanently joined into a single unit. Swaging is a material process to connect and secure multiple parts together by plastic deformation, wherein plastic deformation refers to a deformation that is irreversible, plastic deformation being the opposite of elastic deformation. As illustrated, by the application of a force (such as swaging or riveting tool) the swage pin is deformed to form a swage head 435 that provided a swage joint to join the components into a single permanent unit.

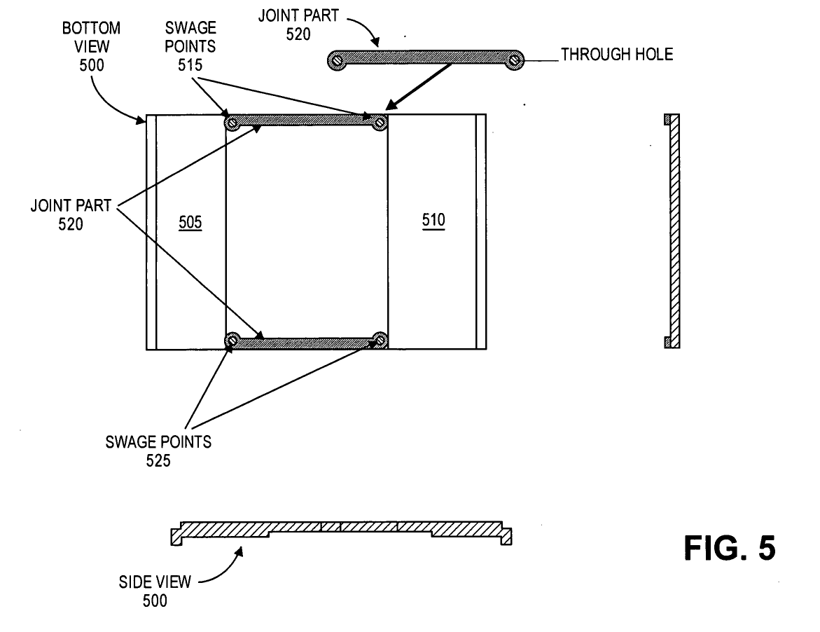

FIG. 5 illustrates an integrated heat spreader including joint parts according to an embodiment. In this illustration, components of an integrated heat spreader may include one or more joint parts that serve to join together larger components. As shown, the components for a particular structure may include a first component 505 and second component 510, wherein the first and second components 505-510 may be joined utilizing one or more joint parts 520, wherein the joint parts include swage points 515 and 525 to allow for the joining of each of the components.

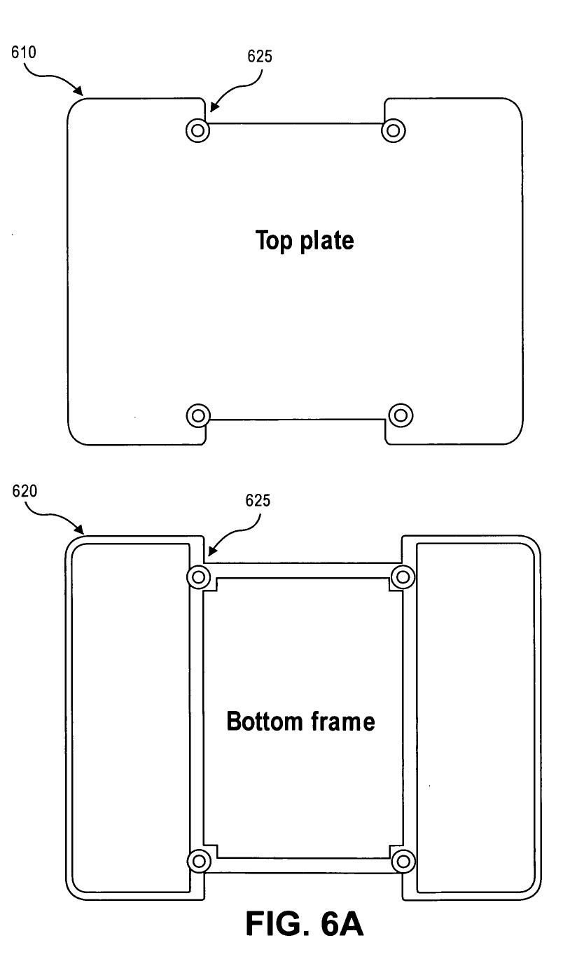

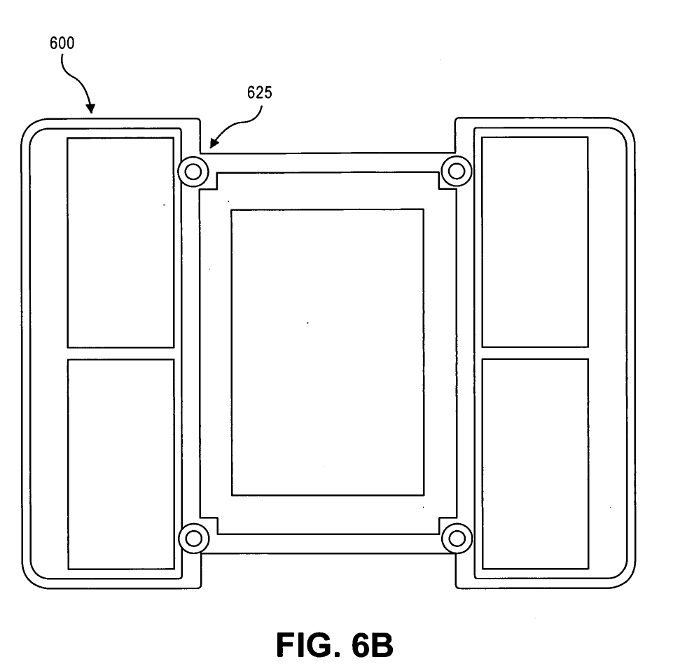

FIG. 6A is an illustration of a frame structure for construction of an integrated heat structure according to an embodiment. In some embodiments, components for construction of an integrated heat spreader may include a bottom frame 620 with swage points 625, wherein the bottom frame may include one or more open windows on to which one or components may be joined by a swage process. In an example, the multiple components may include a top plate 610 with swage points 625, wherein the top plate in this example may align with the bottom frame 620, and wherein the components (and potentially with one or more other components) may be permanently joined with a swaging process to construct a combined integrated heat spreader unit.

FIG. 6B is an illustration of a combined unit including a frame structure for construction of an integrated heat structure according to an embodiment. As illustrated, a combined IHS unit 600 with swage points 625 may include, for example, the bottom frame 610 and top plate 610 joined by a swaging process to generate all or a part of an integrated heater spreader.

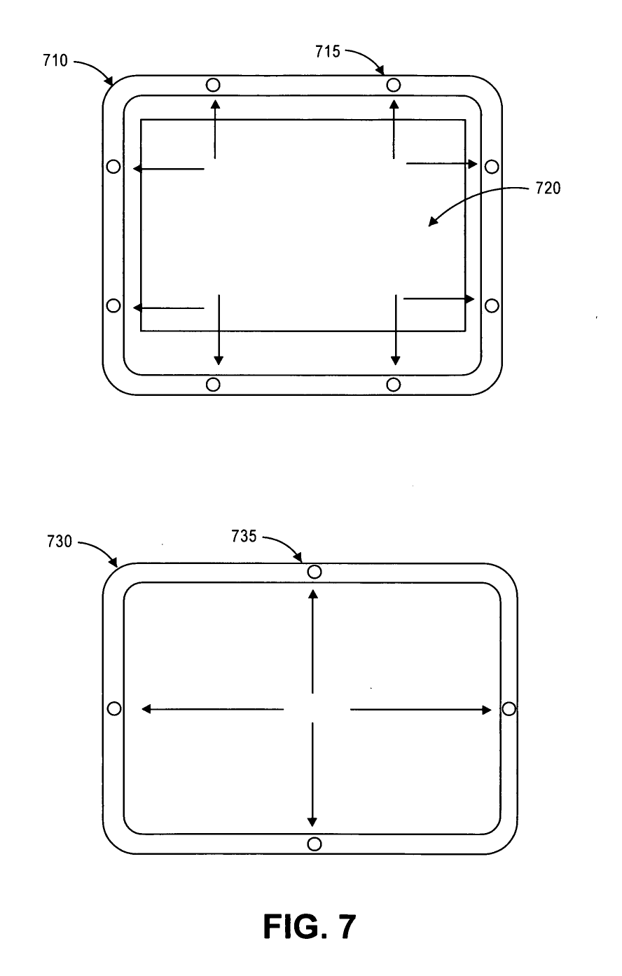

FIG. 7 is an illustration of components for construction of an integrated heat structure according to an embodiment. As illustrated, component 710, with eight swage points 715, and component 730, with four swage point 725, may each be individually designed and stamped for assembly into a frame section. Each such component may include different features, such as the indentation or other feature 720 of component 710, as required for a particular implementation.

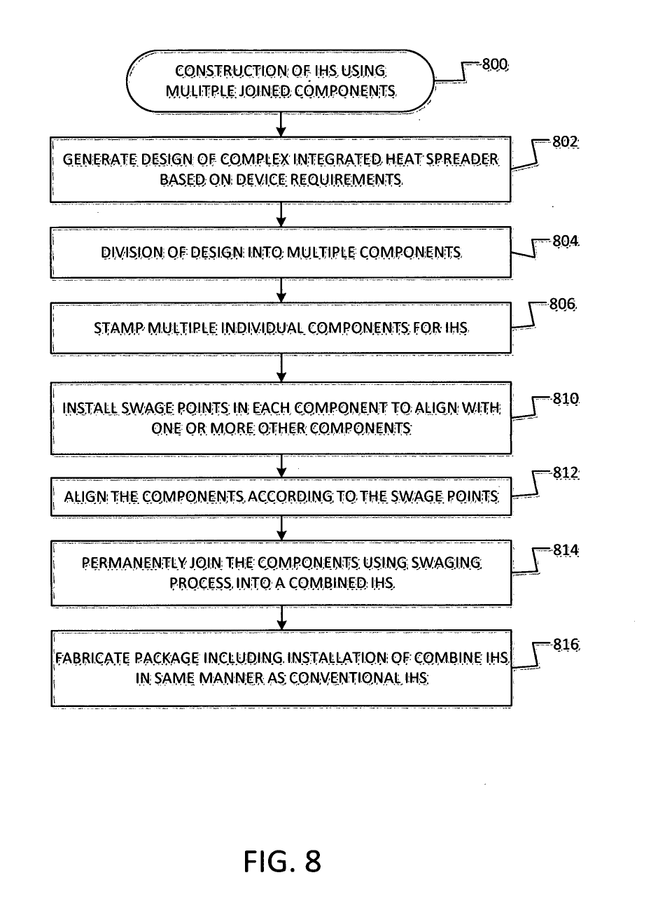

FIG. 8 is a flow chart to illustrate a process for fabrication of an integrated heat spreader using multiple joined components according to an embodiment. In some embodiments, a process for IHS constructions includes:

802: Generate design of complex integrated heat spreader based on device requirements.

804: Division of design into multiple components, wherein each component being less complex than the full IHS design.

806: Upon the design of the components being complete, fabricate multiple individual components for IHS, wherein the individual components may each be fabricated by stamping from a piece of metal, such as copper. However, embodiments are not limited to use of a particular material.

808: Install swage points in each component, where each swage point is to align with a swage point of one or more other components.

810: Align the components according to the swage points.

812: Permanently join the components using swaging process into a combined IHS.

814: Fabricate package including installation of combine IHS in same manner as conventional IHS.

In the description above, for the purposes of explanation, numerous specific details are set forth in order to provide a thorough understanding of the described embodiments. It will be apparent, however, to one skilled in the art that embodiments may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments may include various processes. These processes may be performed by hardware components or may be embodied in computer program or machine-executable instructions, which may be used to cause a general-purpose or special-purpose processor or logic circuits programmed with the instructions to perform the processes. Alternatively, the processes may be performed by a combination of hardware and software.

Portions of various embodiments may be provided as a computer program product, which may include a computer-readable medium having stored thereon computer program instructions, which may be used to program a computer (or other electronic devices) for execution by one or more processors to perform a process according to certain embodiments. The computer-readable medium may include, but is not limited to, magnetic disks, optical disks, compact disk read-only memory (CD-ROM), and magneto-optical disks, read-only memory

(ROM), random access memory (RAM), erasable programmable read-only memory (EPROM), electrically-erasable programmable read-only memory (EEPROM), magnet or optical cards, flash memory, or other type of computer-readable medium suitable for storing electronic instructions. Moreover, embodiments may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present embodiments. It will be apparent to those skilled in the art that many further modifications and adaptations can be made. The particular embodiments are not provided to limit the concept but to illustrate it. The scope of the embodiments is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments, various features are sometimes grouped together in a single embodiment, figure, or description thereof for the purpose of streamlining the disclosure and aiding in the understanding of one or more of the various novel aspects. This method of disclosure, however, is not to be interpreted as reflecting an intention that the claimed embodiments requires more features than are expressly recited in each claim. Rather, as the following claims reflect, novel aspects lie in less than all features of a single foregoing disclosed embodiment. Thus, the claims are hereby expressly incorporated into this description, with each claim standing on its own as a separate embodiment.

In some embodiments, an integrated heat spreader includes multiple components, each of the multiple components including one or more swage points; and a multiple swage joints, each swage joint including a swage pin joining two or more components. In some embodiments, the components are joined into a single integrated heat spreader unit by the swage joints.

In some embodiments, the components are permanently joined by the swage joints.

In some embodiments, each component is a separate stamped unit.

In some embodiments, each component is stamped from copper material.

In some embodiments, each component includes a multiple swage points, wherein each of the swage points is aligned with a swage point of one or more of the other components of the components.

In some embodiments, each swage point is one of a swage hole or a swage pin.

In some embodiments, the integrated heat spreader includes a multiple cavities, and wherein a first cavity is different than a second cavity.

In some embodiments, the components include a first frame component including at least one open window and a second component to be joined to cover the open window.

In some embodiments, a package includes a substrate; chips or packages installed on the substrate; an integrated heat spreader to provide heat spreading for each of the chips or packages. In some embodiments, the integrated heat spreader includes components, each of the components including one or more swage points, and a multiple swage joints, each swage joint including a swage pin with a deformed swage head to join two or more components.

In some embodiments, the components are joined into a single integrated heat spreader by the swage joints.

In some embodiments, the components are permanently joined by the swage joints.

In some embodiments, each component is a separate stamped unit.

In some embodiments, each component includes a swage points, wherein each of the swage points is aligned with a swage point of one or more of the other components of the components.

In some embodiments, each swage point is one of a swage hole or a swage pin.

In some embodiments, the integrated heat spreader a separate cavity for each chip, wherein a first cavity has a different cavity depth than a second cavity.

In some embodiments, a method includes fabricating multiple individual components for an integrated heat spreader; installing one or more swage points in each component; aligning the components according to the swage points of the components; and joining the components using a swaging process to produce a combined integrated heat spreader.

In some embodiments, further including fabricating a package including the combined integrated heat spreader.

In some embodiments, fabricating each of the components includes stamping each of the components separately.

In some embodiments, fabricating each of the plurality of components includes fabricating each of the plurality of components from copper material.

In some embodiments, each component includes multiple swage points, wherein each of the swage points is aligned with a swage point of one or more of the other components.

In some embodiments, each swage point is one of a swage hole or a swage pin.

In some embodiments, joining the components using a swaging process including permanently joining the components into a unit.

What is claimed is:

1. An integrated heat spreader comprising:
a plurality of components, each of the plurality of components including one or more swage points; and
a plurality of swage joints, each swage joint including a swage pin joining two or more components;
wherein the plurality of components are joined into a single integrated heat spreader unit by the plurality of swage joints.

2. The integrated heat spreader of claim 1, wherein the plurality of components are permanently joined by the plurality of swage joints.

3. The integrated heat spreader of claim 1, wherein each component is a separate stamped unit.

4. The integrated heat spreader of claim 3, wherein each component is stamped from copper material.

5. The integrated heat spreader of claim 1, wherein each component includes a plurality of swage points, wherein each of the plurality of swage points is aligned with a swage point of one or more of the other components of the plurality of components.

6. The integrated heat spreader of claim 1, wherein each swage point is one of a swage hole or a swage pin.

7. The integrated heat spreader of claim 1, wherein the integrated heat spreader includes a plurality of cavities, and wherein a first cavity is different than a second cavity.

8. The integrated heat spreader of claim 1, wherein the plurality of components includes a first frame component including at least one open window and a second component to be joined to cover the open window.

9. A package comprising:
a substrate;
a plurality of chips or packages installed on the substrate;
an integrated heat spreader to provide heat spreading for each of the plurality of chips or packages;
wherein the integrated heat spreader includes:
a plurality of components, each of the plurality of components including one or more swage points, and
a plurality of swage joints, each swage joint including a swage pin with a deformed swage head to join two or more components;
wherein the plurality of components are joined into a single integrated heat spreader by the plurality of swage joints.

10. The package of claim 9, wherein the plurality of components are permanently joined by the plurality of swage joints.

11. The package of claim 9, wherein each component is a separate stamped unit.

12. The package of claim 9, wherein each component includes a plurality of swage points, wherein each of the plurality of swage points is aligned with a swage point of one or more of the other components of the plurality of components.

13. The package of claim 9, wherein each swage point is one of a swage hole or a swage pin.

14. The package of claim 9, wherein the integrated heat spreader a separate cavity for each chip, wherein a first cavity has a different cavity depth than a second cavity.

15. A method comprising:
fabricating multiple individual components for an integrated heat spreader;
installing one or more swage points in each component;
aligning the plurality of components according to the swage points of the components; and
joining the plurality of components using a swaging process to produce a combined integrated heat spreader.

16. The method of claim 15, further comprising fabricating a package including the combined integrated heat spreader.

17. The method of claim 15, wherein fabricating each of the plurality of components includes stamping each of the plurality of components separately.

18. The method of claim 15, wherein each component includes a plurality of swage points, wherein each of the plurality of swage points is aligned with a swage point of one or more of the other components of the plurality of components.

19. The method of claim 15, wherein each swage point is one of a swage hole or a swage pin.

20. The method of claim 15, wherein joining the plurality of components using a swaging process including permanently joining the plurality of components into a unit.
